(19) United States
(12) Patent Application Publication
(10) Pub. No.: US 2026/0080950 A1
(43) Pub. Date: Mar. 19, 2026

(54) MEMORY DEVICE, MEMORY CONTROL CIRCUIT, AND READING METHOD

(71) Applicant: Realtek Semiconductor Corporation, Hsinchu (TW)

(72) Inventor: Hsin-Han CHEN, Hsinchu (TW)

(21) Appl. No.: 19/284,665

(22) Filed: Jul. 29, 2025

(30) Foreign Application Priority Data
Sep. 13, 2024 (TW) 113134965

(51) Int. Cl. G11C 16/28; G11C 16/04; G11C 16/08; G11C 16/32

(52) U.S. Cl. CPC G11C 16/28; G11C 16/0483; G11C 16/08; G11C 16/32

(57) ABSTRACT

A memory device includes a memory cell array and a memory control circuit. The memory cell array is coupled to bit lines and complementary bit lines. The memory control circuit includes a driver circuit, a tracking circuit, and a sensor circuit. The driver circuit transmits a word line signal to the memory cell array. The driver circuit includes an assist circuit. The tracking circuit controls a dummy bit line signal according to an under-drive signal. The sensor circuit reads a memory cell in the memory cell array according to the dummy bit line signal. When the assist circuit is turned off, the under-drive signal has a first voltage. When the assist circuit is turned on, the under-drive signal has a second voltage. The second voltage is lower than the first voltage.

### RELATED APPLICATIONS

This application claims priority to Taiwanese Application Serial Number 113134965, filed Sep. 13, 2024, which is herein incorporated by reference.

### BACKGROUND

### Technical Field

The present disclosure relates to memory technology. More particularly, the present disclosure relates to a memory device, a memory control circuit, and a reading method.

### Description of Related Art

With development of technology, various memory devices are developed. Due to applications of dynamic voltage and frequency scaling (DVFS), a range of an operating voltage of a memory device becomes wider. However, in lower operating voltages, it is easy to cause errors due to noise interference.

### SUMMARY

Some aspects of the present disclosure are to provide a memory device. The memory device includes a memory cell array and a memory control circuit. The memory cell array is coupled to a plurality of bit lines and a plurality of complementary bit lines. The memory control circuit is coupled to the memory cell array. The memory control circuit includes a driver circuit, a tracking circuit, and a sensor circuit. The driver circuit is configured to transmit a word line signal to the memory cell array. The driver circuit includes an assist circuit. The tracking circuit is configured to control a dummy bit line signal according to an under-drive signal. The sensor circuit is coupled to the plurality of bit lines and the plurality of complementary bit lines, and is configured to read a memory cell in the memory cell array according to the dummy bit line signal. When the assist circuit is turned off, the under-drive signal has a first voltage. When the assist circuit is turned on, the under-drive signal has a second voltage. The second voltage is lower than the first voltage.

Some aspects of the present disclosure are to provide a memory control circuit. The memory control circuit includes a driver circuit, a tracking circuit, and a sensor circuit. The driver circuit is configured to transmit a word line signal to a memory cell array. The driver circuit includes an assist circuit. The tracking circuit is configured to control a dummy bit line signal according to an under-drive signal. The sensor circuit is coupled to a plurality of bit lines and a plurality of complementary bit lines, and is configured to read a memory cell in the memory cell array according to the dummy bit line signal. When the assist circuit is turned off, the under-drive signal has a first voltage. When the assist circuit is turned on, the under-drive signal has a second voltage. The second voltage is lower than the first voltage.

Some aspects of the present disclosure are to provide a reading method of a memory device. The reading method includes following operations: transmitting, by a driver circuit in a memory control circuit, a word line signal to a memory cell array, in which the driver circuit includes an assist circuit; controlling, by a tracking circuit in the memory control circuit, a dummy bit line signal according to an under-drive signal, in which when the assist circuit is turned off, the under-drive signal has a first voltage, in which when the assist circuit is turned on, the under-drive signal has a second voltage, in which the second voltage is lower than the first voltage; and reading, by a sensor circuit in the memory control circuit, a memory cell in the memory cell array according to the dummy bit line signal.

### BRIEF DESCRIPTION OF THE DRAWINGS

The disclosure can be more fully understood by reading the following detailed description of the embodiment, with reference made to the accompanying drawings as follows:

FIG. 1 is a schematic diagram of a memory device according to some embodiments of the present disclosure.

FIG. 2 is a waveform diagram of multiple signals according to some embodiments of the present disclosure.

FIG. 3 to FIG. 10 are schematic diagrams of tracking circuits according to some embodiments of the present disclosure.

FIG. 11 is a schematic diagram of a reading method according to some embodiments of the present disclosure.

### DETAILED DESCRIPTION

In the present disclosure, “connected” or “coupled” may refer to “electrically connected” or “electrically coupled. ” “Connected” or “coupled” may also refer to operations or actions between two or more elements.

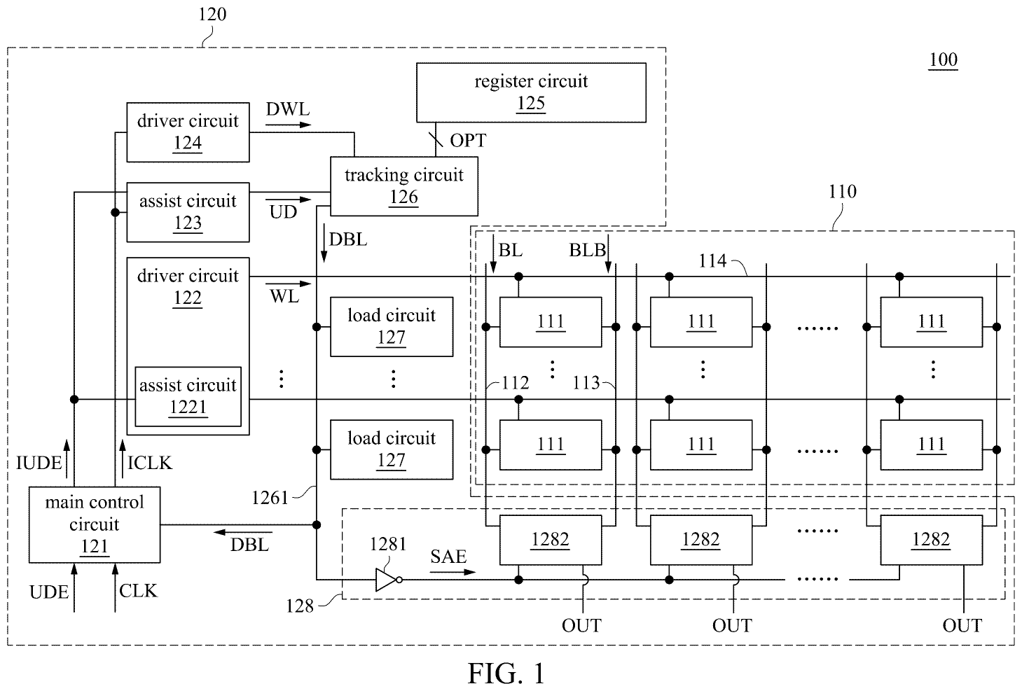

Reference is made to FIG. 1. FIG. 1 is a schematic diagram of a memory device 100 according to some embodiments of the present disclosure. In some embodiments, the memory device 100 can be a static random-access memory (SRAM), but the present disclosure is not limited thereto.

As illustrated in FIG. 1, the memory device 100 includes a memory cell array 110 and a memory control circuit 120. The memory control circuit 120 is coupled to the memory cell array 110 and is configured to control (write and read) the memory cell array 110.

The memory cell array 110 includes multiple memory cells 111. The memory cells 111 are arranged in an array form. The memory cells 111 are coupled to multiple bit lines, multiple complementary bit lines, and multiple word lines. For example, the memory cells 111 in a first column are coupled to a bit line 112 and a complementary bit line 113. The memory cells 111 in a first row are coupled to a word line 114. Other rows and other columns are with similar architectures.

The memory control circuit 120 includes a main control circuit 121, a driver circuit 122, an assist circuit 123, a driver circuit 124, a register circuit 125, a tracking circuit 126, multiple load circuits 127, and a sensor circuit 128.

The main control circuit 121 generates an internal under-drive enable signal IUDE according to an under-drive enable signal UDE, and generates an internal clock signal ICLK according to a clock signal CLK.

The driver circuit 122 generates a word line signal WL according to the internal under-drive enable signal IUDE and the internal clock signal ICLK, and transmits the word line signal WL to the memory cells 111. For example, the driver circuit 122 can transmit the word line signal WL through the word line 114 to the memory cells 111 in the first row.

The driver circuit 122 includes an assist circuit 1221. In some embodiments, the under-drive enable signal UDE can be used to turn on or turn off the assist circuit 1221. To be more specific, due to applications of dynamic voltage and frequency scaling (DVFS), a range of an operating voltage of the memory device 100 becomes wider. When the memory device 100 operates in a lower operating voltage, the under-drive enable signal UDE can have a high logic level. The main control circuit 121 can generate the internal under-drive enable signal IUDE with a high logic level according to the under-drive enable signal UDE with the high logic level. The assist circuit 1221 can be turned on according to the internal under-drive enable signal IUDE with the high logic level. When the assist circuit 1221 is turned on, a voltage of the word line signal WL is reduced to reduce noise interference on the memory cells 111. On the contrary, when the memory device 100 does not operates in the lower operating voltage, the under-drive enable signal UDE can have a low logic level. The main control circuit 121 can generate the internal under-drive enable signal IUDE with a low logic level according to the under-drive enable signal UDE with the low logic level. The assist circuit 1221 can be turned off according to the internal under-drive enable signal IUDE with the low logic level. In some embodiments, the assist circuit 1221 is a read/write assist circuit. The read/write assist circuit can be implemented by an under-drive circuit with a buffer.

The assist circuit 123 generates an under-drive signal UD according to the internal under-drive enable signal IUDE and the internal clock signal ICLK, and transmits the under-drive signal UD to the tracking circuit 126. In some embodiments, the assist circuit 123 can be implemented by an under-drive circuit with a buffer.

The driver circuit 124 generates a dummy word line signal DWL according to the internal clock signal ICLK, and transmits the dummy word line signal DWL to the tracking circuit 126.

The register circuit 125 generates one or more selection signals OPT, and transmits the selection signals OPT to the tracking circuit 126. In some embodiments, the register circuit 125 can be implemented by one or more registers.

The tracking circuit 126 controls a dummy bit line signal DBL on a dummy bit line 1261 according to the under-drive signal UD, the dummy word line signal DWL, and the selection signals OPT. The dummy bit line signal DBL can be transmitted to the sensor circuit 128 through the dummy bit line 1261.

The load circuits 127 are coupled to the dummy bit line 1261. In some embodiments, a circuit architecture of each of the load circuits 127 can be the same or similar to a circuit architecture of each of the memory cells 111, and a quantity of the load circuits 127 can be equal to a quantity of the memory cells in one column to simulate capacitance-resistance environment of each column of the memory cells 111.

The sensor circuit 128 includes an inverter 1281 and multiple sensing amplifiers 1282. The inverter 1281 is coupled between the dummy bit line 1261 and the sensing amplifiers 1282. The sensing amplifiers 1282 is coupled to the bit lines and the complementary bit lines. The inverter 1281 inverts the dummy bit line signal DBL to generate an enable signal SAE. The enable signal SAE is transmitted to the sensing amplifiers 1282 to enable the sensing amplifiers 1282. For example, when a first sensing amplifier 1282 is enabled, this sensing amplifier 1282 can sense a bit line signal BL on the bit line 112 and a complementary bit line signal BLB on the complementary bit line 113, and amplify a voltage difference between the bit line signal BL and the complementary bit line signal BLB to generate an output signal OUT so as to complete corresponding read operation.

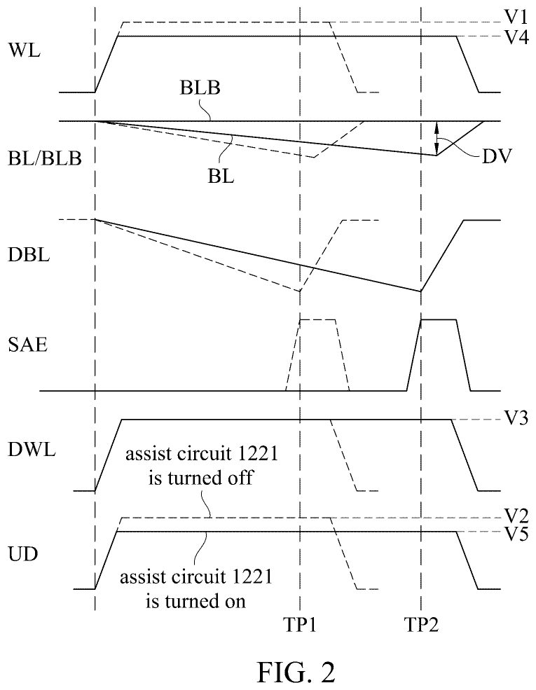

References are made to FIG. 1 and FIG. 2. FIG. 2 is a waveform diagram of multiple signals according to some embodiments of the present disclosure.

It is noted that, in FIG. 2, dotted lines illustrate a condition when the assist circuit 1221 is turned off, and solid lines illustrate a condition when the assist circuit 1221 is turned on. In addition, FIG. 2 illustrates that the memory cells 111 pulls down the bit line signal BL. In other embodiments, the memory cells 111 pulls down the complementary bit line signal BLB.

Refer to the dotted lines in FIG. 2. When the memory device 100 does not operate in the lower operating voltage, the assist circuit 1221 is turned off. The driver circuit 122 outputs the word line signal WL with a voltage V1 and the word line signal WL has a narrower pulse width. The assist circuit 123 outputs the under-drive signal UD with a voltage V2 and the under-drive signal UD has a narrower pulse width. The driver circuit 124 outputs the dummy word line signal DWL with a voltage V3 and the dummy word line signal DWL has a narrower pulse width. The word line signal WL can turn on the memory cells 111 such that the bit line signal BL is pulled down by the memory cells 111. The dummy bit line signal DBL is pulled down by the tracking circuit 126. At a timing point TP1, the dummy bit line signal DBL is pulled down to a predetermined voltage, causing the enable signal SAE to turn to a high logic level to enable the sensing amplifiers 1282. At the same time, since the voltage difference between the bit line signal BL and the complementary bit line signal BLB is large enough, the corresponding sensing amplifier 1282 can amplify and read out the voltage difference correctly.

Refer to the solid lines in FIG. 2. When the memory device 100 operates in the lower operating voltage, the assist circuit 1221 is turned on. The driver circuit 122 outputs the word line signal WL with a voltage V4 (lower than the voltage V1) and the word line signal WL has a wider pulse width. The assist circuit 123 outputs the under-drive signal UD with a voltage V5 (lower than the voltage V2) and the under-drive signal UD has a wider pulse width. The driver circuit 124 outputs the dummy word line signal DWL with the voltage V3 and the dummy word line signal DWL has a wider pulse width. It should be noted that the main control circuit 121 adjusts the internal clock signal ICLK according to the dummy bit line signal DBL, and the driver circuit 124 adjusts the pulse width of the dummy word line signal DWL according to the internal clock signal ICLK.

In some embodiments, when the voltage V2 is 0.8 volts, the voltage V5 can be 0.72 volts. In this example, a voltage difference between the voltage V5 and the voltage V2 is 10% of the voltage V2. However, the present disclosure is not limited to these voltage values and these voltage difference value above. In other embodiments, the voltage difference between the voltage V5 and the voltage V2 can be more than 10% of the voltage V2.

As described above, in some related approaches, when the memory device 100 operates in the lower operating region, since the voltage of the word line signal WL is reduced, the noise interference on the memory cells 111 can be reduced. However, this also weakens a pull-down ability of the memory cells 111 for pulling down the bit line signal BL or pulling down the complementary bit line signal BLB, causing the voltage difference between the bit line signal BL and the complementary bit line signal BLB to be too small to be read out correctly.

Compared to the related approaches mentioned above, in the present disclosure, when the memory device 100 operates in the lower operating voltages, the ability of the tracking circuit 126 for pulling down the dummy bit line signal DBL also becomes weaker due to the under-drive signal UD with the lower voltage V5 (details are described in following paragraphs). Thus, the dummy bit line signal DBL is pulled down to the predetermined voltage at a later timing point TP2 such that the enable signal SAE turns to have a high logic level at the later timing point TP2 to enable the sensing amplifiers 1282. At the timing point TP2, the voltage difference DV between the bit line signal BL and the complementary bit line signal BLB is large enough such that the sensing amplifier 1282 can amplify and read out the voltage difference DV correctly.

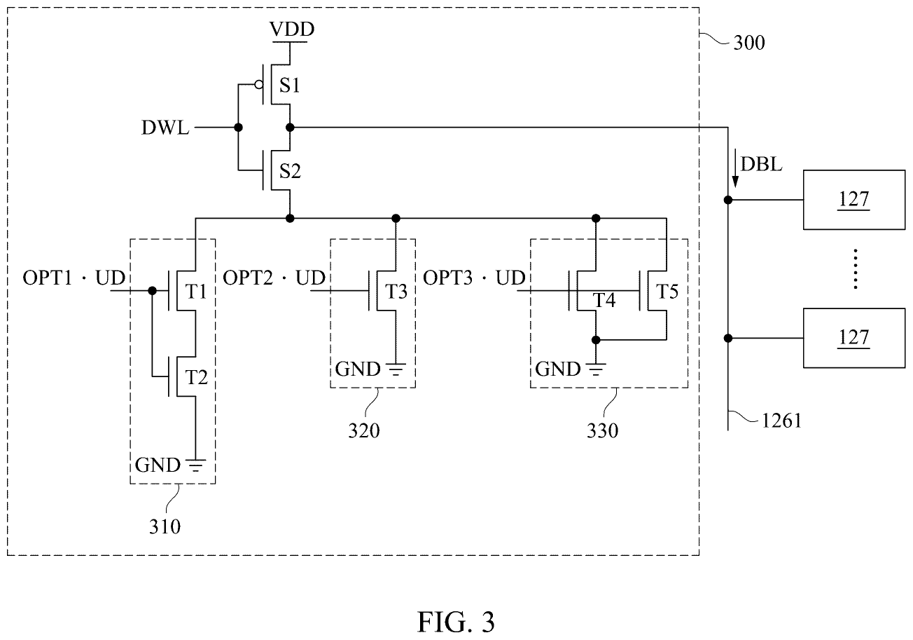

References are made to FIG. 1, FIG. 2, and FIG. 3. FIG. 3 is a schematic diagram of a tracking circuit 300 according to some embodiments of the present disclosure.

As illustrated in FIG. 3, the tracking circuit 300 includes a pull-up switch S1, a pull-down switch S2, a selection circuit 310, a selection circuit 320, and a selection circuit 330. In this example, the pull-up switch S1 is implemented by a P-type switch, the pull-down switch S2 is implemented by an N-type switch, but the present disclosure is not limited thereto.

The pull-up switch S1 is coupled to a power source VDD. The pull-up switch S1 and the pull-down switch S2 is coupled in series at a middle node, and this middle node is coupled to the dummy bit line 1261. The pull-up switch S1 and the pull-down switch S2 are controlled (to be turned on or turned off) by the dummy word line signal DWL.

The selection circuit 310, the selection circuit 320, and the selection circuit 330 are coupled in parallel between the pull-down switch S2 and a ground terminal GND. In the example of FIG. 3, the selection circuit 310 includes a transistor T1 and a transistor T2. The transistor T1 and the transistor T2 are coupled in series between the pull-down switch S2 and the ground terminal GND, and are controlled (to be turned on or turned off) by a combination signal of a selection signal OPT1 and the under-drive signal UD. The selection circuit 320 includes a transistor T3. The transistor T3 is coupled between the pull-down switch S2 and the ground terminal GND, and is controlled (to be turned on or turned off) by a combination signal of a selection signal OPT2 and the under-drive signal UD. The selection circuit 330 includes a transistor T4 and the transistor T5. The transistor T4 and the transistor T5 are coupled in parallel between the pull-down switch S2 and the ground terminal GND, and controlled (to be turned on or turned off) by a combination signal of a selection signal OPT3 and the under-drive signal UD. In this example, the transistors T1-T5 are implemented by N-type transistors, but the present disclosure is not limited thereto.

The combination signals mentioned above can be signals generated by an AND gate. For example, the AND gate can be used to perform an AND operation on the selection signal OPT1 and the under-drive signal UD to generate the combination signal thereof. Other combination signals have similar operations, so they are not described herein again.

Since the circuit architectures of the selection circuit 310, the selection circuit 320, and the selection circuit 330 are different from each other, the selection circuit 310, the selection circuit 320, and the selection circuit 330 have different pull-down abilities for pulling down the dummy bit line signal DBL. The implementations of the selection circuit 310, the selection circuit 320, and the selection circuit 330 in FIG. 3 are merely for illustration. Other implementations of the selection circuit 310, the selection circuit 320, and the selection circuit 330 are within the contemplated scopes of the present disclosure.

In practical applications, the under-drive signal UD with the lower voltage V5 is used to determine (e.g., weaken) the pull-down abilities of the selection circuit 310, the selection circuit 320, and the selection circuit 330 when the assist circuit 1221 is turned on, and the logic levels of the selection signals OPT1-OPT3 are determined according to practical requirements. Thus, this can selectively turn on one or more of the selection circuit 310, the selection circuit 320, and the selection circuit 330 so as to determine (e.g., delay) the timing point (e.g., the timing point TP2) when the dummy bit line signal DBL is pulled down to the predetermined voltage.

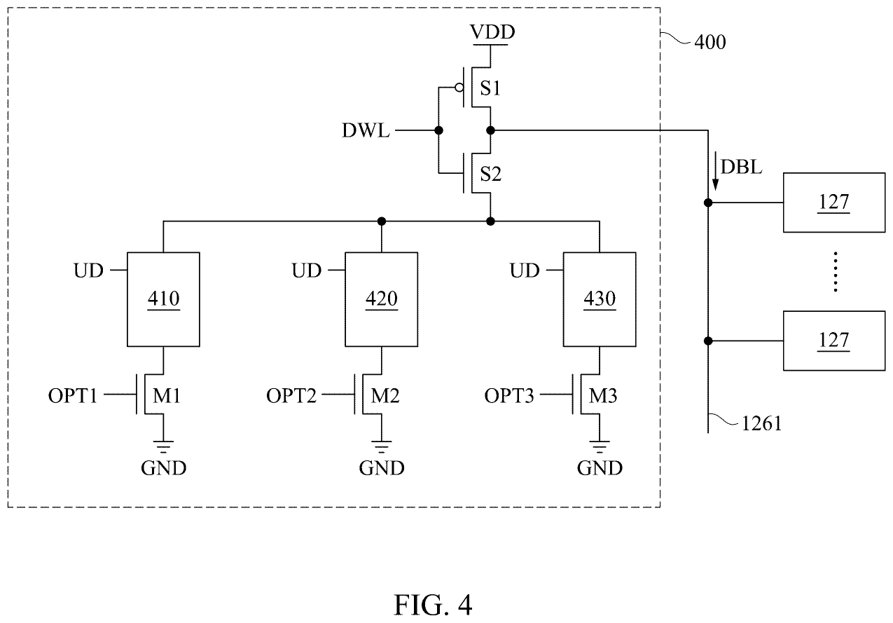

References are made to FIG. 1, FIG. 2, and FIG. 4. FIG. 4 is a schematic diagram of a tracking circuit 400 according to some embodiments of the present disclosure.

As illustrated in FIG. 4, the tracking circuit 400 includes a pull-up switch S1, a pull-down switch S2, a selection circuit 410, a selection circuit 420, a selection circuit 430, a selection switch M1, a selection switch M2, and a selection switch M3.

The pull-up switch S1 is coupled to the power source VDD. The pull-up switch S1 and the pull-down switch S2 are coupled in series at a middle node, and the middle node is coupled to the dummy bit line 1261. The pull-up switch S1 and the pull-down switch S2 are controlled by the dummy word line signal DWL.

The selection circuit 410, the selection circuit 420, and the selection circuit 430 are coupled to the pull-down switch S2, and are controlled by the under-drive signal UD. In some embodiments, the selection circuit 410, the selection circuit 420, and the selection circuit 430 can be implemented by the selection circuit 310, the selection circuit 320, and the selection circuit 330 in FIG. 3 respectively, but the present disclosure is not limited thereto.

The selection switch M1 is coupled between the selection circuit 410 and the ground terminal GND, and is controlled by the selection signal OPT1. The selection switch M2 is coupled between the selection circuit 420 and the ground terminal GND, and is controlled by the selection signal OPT2. The selection switch M3 is coupled between the selection circuit 430 and the ground terminal GND, and is controlled by the selection signal OPT3. In this example, the selection switches M1-M3 are implemented by N-type transistors, but the present disclosure is not limited thereto.

In practical applications, the under-drive signal UD with the lower voltage V5 is used to determine (e.g., weaken) the pull-down abilities of the selection circuit 410, the selection circuit 420, and the selection circuit 430 when the assist circuit 1221 is turned on, and the logic levels of the selection signals OPT1-OPT3 are determined according to practical requirements. Thus, this can selectively turn on one or more of the selection switch M1, the selection switch M2, and the selection switch M3 so as to determine (e.g., delay) the timing point (e.g., the timing point TP2) when the dummy bit line signal DBL is pulled down to the predetermined voltage.

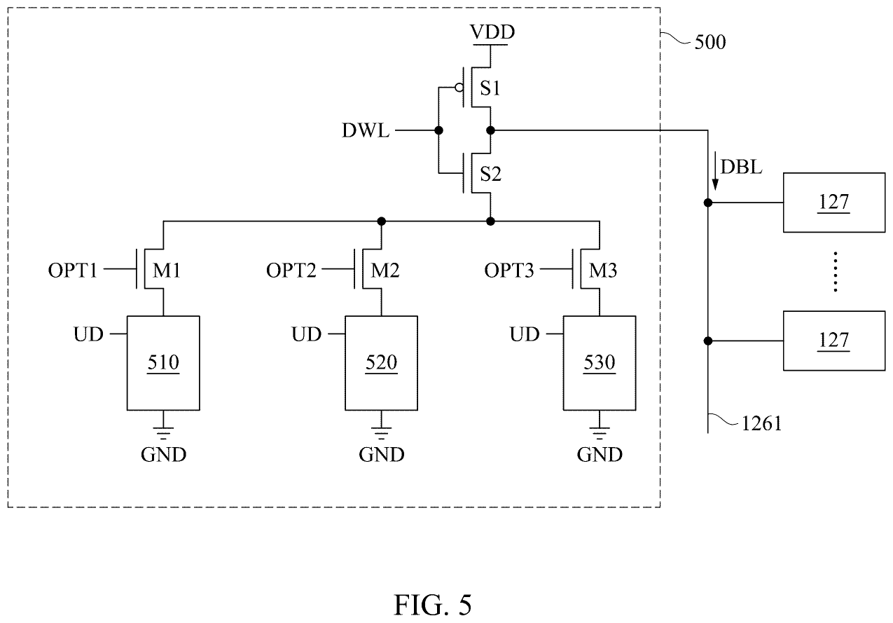

References are made to FIG. 1, FIG. 2, and FIG. 5. FIG. 5 is a schematic diagram of a tracking circuit 500 according to some embodiments of the present disclosure.

As illustrated in FIG. 5, the tracking circuit 500 includes a pull-up switch S1, a pull-down switch S2, a selection switch M1, a selection switch M2, a selection switch M3, a selection circuit 510, a selection circuit 520, and a selection circuit 530.

The pull-up switch S1 is coupled to the power source VDD. The pull-up switch S1 and the pull-down switch S2 are coupled in series at a middle node, and the middle node is coupled to the dummy bit line 1261. The pull-up switch S1 and the pull-down switch S2 are controlled by the dummy word line signal DWL.

The selection circuit 510, the selection circuit 520, and the selection circuit 530 are coupled to the ground terminal GND, and are controlled by the under-drive signal UD. In some embodiments, the selection circuit 510, the selection circuit 520, and the selection circuit 530 can be implemented by the selection circuit 310, the selection circuit 320, and the selection circuit 330 in FIG. 3 respectively, but the present disclosure is not limited thereto.

The selection switch M1 is coupled between the pull-down switch S2 and the selection circuit 510, and is controlled by the selection signal OPT1. The selection switch M2 is coupled between the pull-down switch S2 and the selection circuit 520, and is controlled by the selection signal OPT2. The selection switch M3 is coupled between the pull-down switch S2 and the selection circuit 530, and is controlled by the selection signal OPT3.

In practical applications, the under-drive signal UD with the lower voltage V5 is used to determine (e.g., weaken) the pull-down abilities of the selection circuit 510, the selection circuit 520, and the selection circuit 530 when the assist circuit 1221 is turned on, and the logic levels of the selection signals OPT1-OPT3 are determined according to practical requirements. Thus, this can selectively turn on one or more of the selection switch M1, the selection switch M2, and the selection switch M3 so as to determine (e.g., delay) the timing point (e.g., the timing point TP2) when the dummy bit line signal DBL is pulled down to the predetermined voltage.

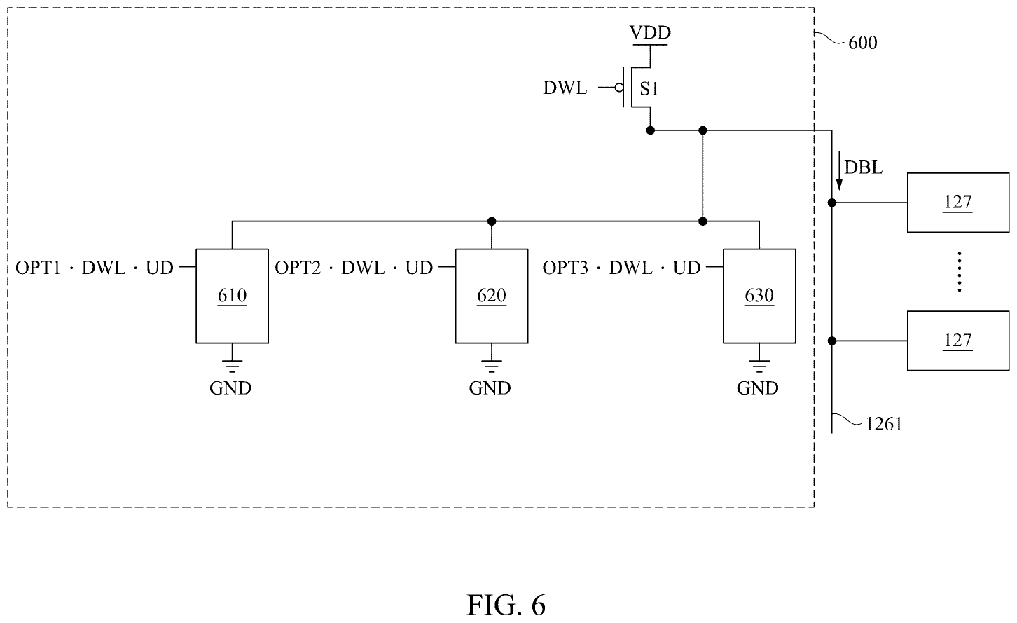

References are made to FIG. 1, FIG. 2, and FIG. 6. FIG. 6 is a schematic diagram of a tracking circuit 600 according to some embodiments of the present disclosure.

As illustrated in FIG. 6, the tracking circuit 600 includes a pull-up switch S1, a selection circuit 610, a selection circuit 620, and a selection circuit 630.

The pull-up switch S1 is coupled between the power source VDD and the dummy bit line 1261, and is controlled by the dummy word line signal DWL.

The selection circuit 610, the selection circuit 620, and the selection circuit 630 are coupled in parallel between the dummy bit line 1261 and the ground terminal GND. In some embodiments, the selection circuit 610, the selection circuit 620, and the selection circuit 630 can be implemented by the selection circuit 310, the selection circuit 320, and the selection circuit 330 in FIG. 3 respectively, but the present disclosure is not limited thereto.

The selection circuit 610 is controlled by a combination signal of the selection signal OPT1, the dummy word line signal DWL, and the under-drive signal UD. The selection circuit 620 is controlled by a combination signal of the selection signal OPT2, the dummy word line signal DWL, and the under-drive signal UD. The selection circuit 630 is controlled by a combination signal of the selection signal OPT3, the dummy word line signal DWL, and the under-drive signal UD.

The combination signals mentioned above can be signals generated by an AND gate. For example, the AND gate can be used to perform an AND operation on the selection signal OPT1, the dummy word line signal DWL, and the under-drive signal UD to generate the combination signal thereof. Other combination signals have similar operations, so they are not described herein again.

In practical applications, the under-drive signal UD with the lower voltage V5 is used to determine (e.g., weaken) the pull-down abilities of the selection circuit 610, the selection circuit 620, and the selection circuit 630 when the assist circuit 1221 is turned on, and the logic levels of the selection signals OPT1-OPT3 are determined according to practical requirements. Thus, this can selectively turn on one or more of the selection circuit 610, the selection circuit 620, and the selection circuit 630 so as to determine (e.g., delay) the timing point (e.g., the timing point TP2) when the dummy bit line signal DBL is pulled down to the predetermined voltage.

In addition, in some other embodiments, the selection circuit 610, the selection circuit 620, and the selection circuit 630 may not be implemented by the selection circuit 310, the selection circuit 320, and the selection circuit 330 in FIG. 3. Taking the selection circuit 610 as an example, the selection circuit 610 can include multiple transistors, some of transistors are controlled by the selection signal OPT1, some of transistors are controlled by the dummy word line signal DWL, and other transistors are controlled by the under-drive signal UD. Or, the selection circuit 610 can include multiple transistors, some of transistors are controlled by a combination signal of two of the selection signal OPT1, the dummy word line signal DWL, and the under-drive signal UD, and other transistor is controlled by a remaining one of the three signals.

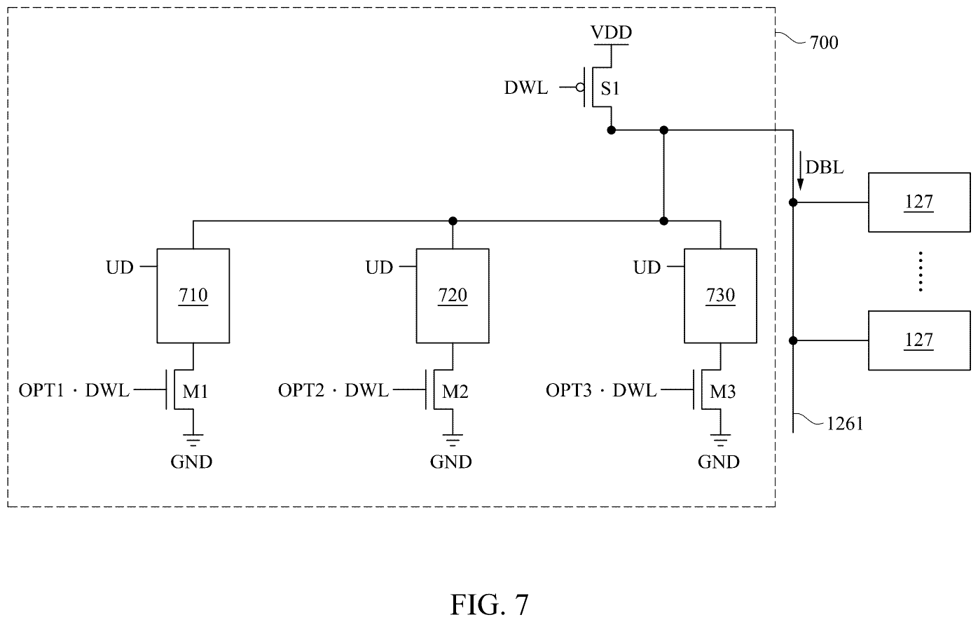

References are made to FIG. 1, FIG. 2, and FIG. 7. FIG. 7 is a schematic diagram of a tracking circuit 700 according to some embodiments of the present disclosure.

As illustrated in FIG. 7, the tracking circuit 700 includes a pull-up switch S1, a selection circuit 710, a selection circuit 720, a selection circuit 730, a selection switch M1, a selection switch M2, and a selection switch M3.

The pull-up switch S1 is coupled between the power source VDD and the dummy bit line 1261, and is controlled by the dummy word line signal DWL.

The selection circuit 710, the selection circuit 720, and the selection circuit 730 are coupled to the dummy bit line 1261, and are controlled by the under-drive signal UD. In some embodiments, the selection circuit 710, the selection circuit 720, and the selection circuit 730 can be implemented by the selection circuit 310, the selection circuit 320, and the selection circuit 330 in FIG. 3 respectively, but the present disclosure is not limited thereto.

The selection switch M1 is coupled between the selection circuit 710 and the ground terminal GND, and is controlled by a combination signal of the selection signal OPT1 and the dummy word line signal DWL. The selection switch M2 is coupled between the selection circuit 720 and the ground terminal GND, and is controlled by a combination signal of the selection signal OPT2 and the dummy word line signal DWL. The selection switch M3 is coupled between the selection circuit 730 and the ground terminal GND, and is controlled by a combination signal of the selection signal OPT3 and the dummy word line signal DWL.

The combination signals mentioned above can be signals generated by an AND gate. For example, the AND gate can be used to perform an AND operation on the selection signal OPT1 and the dummy word line signal DWL to generate the combination signal thereof. Other combination signals have similar operations, so they are not described herein again.

In practical applications, the under-drive signal UD with the lower voltage V5 is used to determine (e.g., weaken) the pull-down abilities of the selection circuit 710, the selection circuit 720, and the selection circuit 730 when the assist circuit 1221 is turned on, and the logic levels of the selection signals OPT1-OPT3 are determined according to practical requirements. Thus, this can selectively turn on one or more of the selection switch M1, the selection switch M2, and the selection switch M3 so as to determine (e.g., delay) the timing point (e.g., the timing point TP2) when the dummy bit line signal DBL is pulled down to the predetermined voltage.

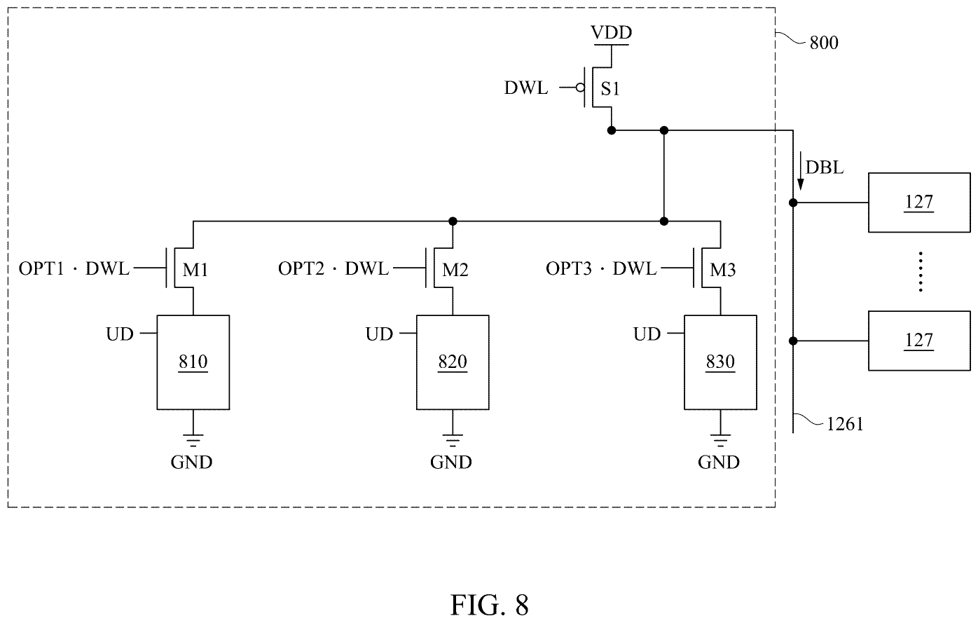

References are made to FIG. 1, FIG. 2, and FIG. 8. FIG. 8 is a schematic diagram of a tracking circuit 800 according to some embodiments of the present disclosure.

As illustrated in FIG. 8, the tracking circuit 800 includes a pull-up switch S1, a selection switch M1, a selection switch M2, a selection switch M3, a selection circuit 810, a selection circuit 820, and a selection circuit 830.

The pull-up switch S1 is coupled between the power source VDD and the dummy bit line 1261, and is controlled by the dummy word line signal DWL.

The selection switch M1, the selection switch M2, and the selection switch M3 are coupled to the dummy bit line 1261. The selection switch M1 is controlled by a combination signal of the selection signal OPT1 and the dummy word line signal DWL. The selection switch M2 is controlled by a combination signal of the selection signal OPT2 and the dummy word line signal DWL. The selection switch M3 is controlled by a combination signal of the selection signal OPT3 and the dummy word line signal DWL.

The combination signals mentioned above can be signals generated by an AND gate. For example, the AND gate can be used to perform an AND operation on the selection signal OPT1 and the dummy word line signal DWL to generate the combination signal thereof. Other combination signals have similar operations, so they are not described herein again.

The selection circuit 810 is coupled between the selection switch M1 and the ground terminal GND, and is controlled by the under-drive signal UD. The selection circuit 820 is coupled between the selection switch M2 and the ground terminal GND, and is controlled by the under-drive signal UD. The selection circuit 830 is coupled between the selection switch M3 and the ground terminal GND, and is controlled by the under-drive signal UD. In some embodiments, the selection circuit 810, the selection circuit 820, and the selection circuit 830 can be implemented by the selection circuit 310, the selection circuit 320, and the selection circuit 330 in FIG. 3 respectively, but the present disclosure is not limited thereto.

In practical applications, the under-drive signal UD with the lower voltage V5 is used to determine (e.g., weaken) the pull-down abilities of the selection circuit 810, the selection circuit 820, and the selection circuit 830 when the assist circuit 1221 is turned on, and the logic levels of the selection signals OPT1-OPT3 are determined according to practical requirements. Thus, this can selectively turn on one or more of the selection switch M1, the selection switch M2, and the selection switch M3 so as to determine (e.g., delay) the timing point (e.g., the timing point TP2) when the dummy bit line signal DBL is pulled down to the predetermined voltage.

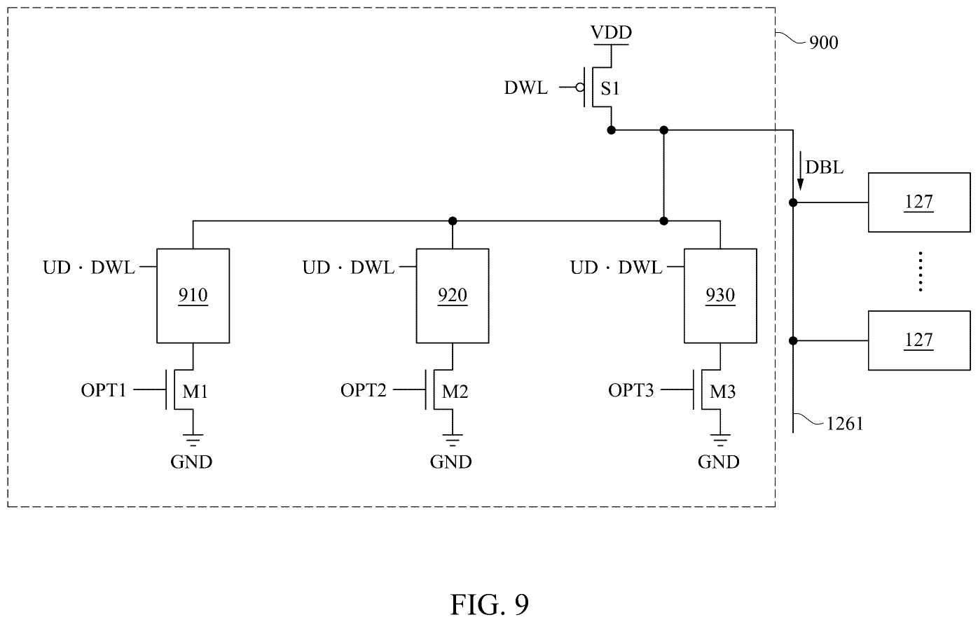

References are made to FIG. 1, FIG. 2, and FIG. 9. FIG. 9 is a schematic diagram of a tracking circuit 900 according to some embodiments of the present disclosure.

As illustrated in FIG. 9, the tracking circuit 900 includes a pull-up switch S1, a selection circuit 910, a selection circuit 920, a selection circuit 930, a selection switch M1, a selection switch M2, and a selection switch M3.

The pull-up switch S1 is coupled between the power source VDD and the dummy bit line 1261, and is controlled by the dummy word line signal DWL.

The selection circuit 910, the selection circuit 920, and the selection circuit 930 are coupled to the dummy bit line 1261, and are controlled by a combination signal of the under-drive signal UD and the dummy word line signal DWL. In some embodiments, the selection circuit 910, the selection circuit 920, and the selection circuit 930 can be implemented by the selection circuit 310, the selection circuit 320, and the selection circuit 330 in FIG. 3 respectively, but the present disclosure is not limited thereto.

The combination signals mentioned above can be signals generated by an AND gate. For example, the AND gate can be used to perform an AND operation on the under-drive signal UD and the dummy word line signal DWL to generate the combination signal thereof. Other combination signals have similar operations, so they are not described herein again.

The selection switch M1 is coupled between the selection circuit 910 and the ground terminal GND, and is controlled by the selection signal OPT1. The selection switch M2 is coupled between the selection circuit 920 and the ground terminal GND, and is controlled by the selection signal OPT2. The selection switch M3 is coupled between the selection circuit 930 and the ground terminal GND, and is controlled by the selection signal OPT3.

In practical applications, the under-drive signal UD with the lower voltage V5 is used to determine (e.g., weaken) the pull-down abilities of the selection circuit 910, the selection circuit 920, and the selection circuit 930 when the assist circuit 1221 is turned on, and the logic levels of the selection signals OPT1-OPT3 are determined according to practical requirements. Thus, this can selectively turn on one or more of the selection switch M1, the selection switch M2, and the selection switch M3 so as to determine (e.g., delay) the timing point (e.g., the timing point TP2) when the dummy bit line signal DBL is pulled down to the predetermined voltage.

In addition, in some other embodiments, the selection circuit 910, the selection circuit 920, and the selection circuit 930 may not be implemented by the selection circuit 310, the selection circuit 320, and the selection circuit 330 in FIG. 3. In these embodiments, taking the selection circuit 910 as an example, the selection circuit 910 can include multiple transistors, some of the transistors are controlled by the under-drive signal UD, and other transistors are controlled by the dummy word line signal DWL.

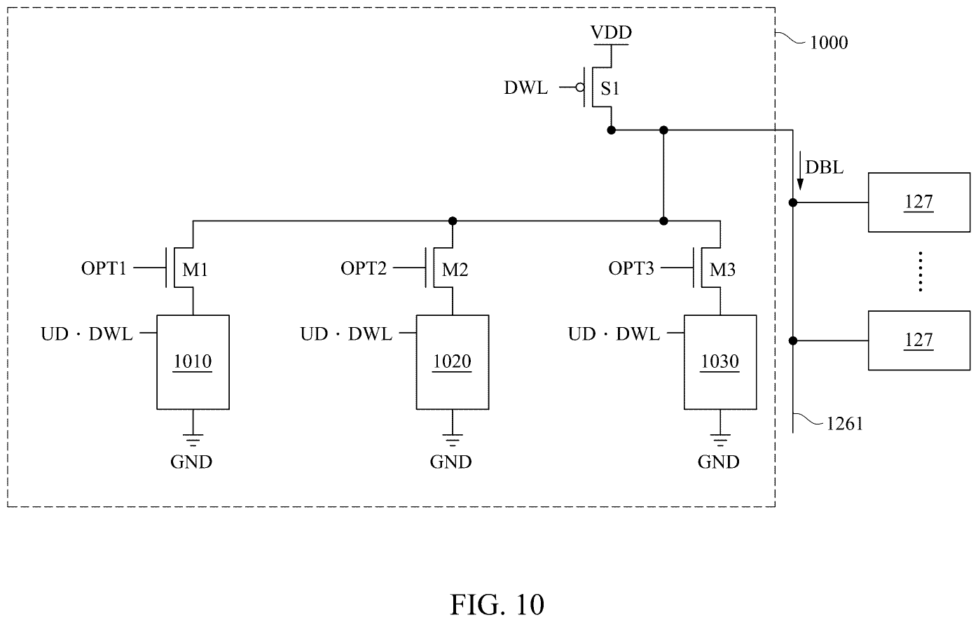

References are made to FIG. 1, FIG. 2, and FIG. 10. FIG. 10 is a schematic diagram of a tracking circuit 1000 according to some embodiments of the present disclosure.

As illustrated in FIG. 10, the tracking circuit 1000 includes a pull-up switch S1, a selection switch M1, a selection switch M2, a selection switch M3, a selection circuit 1010, a selection circuit 1020, and a selection circuit 1030.

The pull-up switch S1 is coupled between the power source VDD and the dummy bit line 1261, and is controlled by the dummy word line signal DWL.

The selection switch M1, the selection switch M2, and the selection switch M3 are coupled to the dummy bit line 1261. The selection switch M1 is controlled by the selection signal OPT1. The selection switch M2 is controlled by the selection signal OPT2. The selection switch M3 is controlled by the selection signal OPT3.

The selection circuit 1010 is coupled between the selection switch M1 and the ground terminal GND, and is controlled by a combination signal of the under-drive signal UD and the dummy word line signal DWL. The selection circuit 1020 is coupled between the selection switch M2 and the ground terminal GND, and is controlled by a combination signal of the under-drive signal UD and the dummy word line signal DWL. The selection circuit 1030 is coupled between the selection switch M3 and the ground terminal GND, and is controlled by a combination signal of the under-drive signal UD and the dummy word line signal DWL. In some embodiments, the selection circuit 1010, the selection circuit 1020, and the selection circuit 1030 can be implemented by the selection circuit 310, the selection circuit 320, and the selection circuit 330 in FIG. 3 respectively, but the present disclosure is not limited thereto.

The combination signals mentioned above can be signals generated by an AND gate. For example, the AND gate can be used to perform an AND operation on the under-drive signal UD and the dummy word line signal DWL to generate the combination signal thereof. Other combination signals have similar operations, so they are not described herein again.

In practical applications, the under-drive signal UD with the lower voltage V5 is used to determine (e.g., weaken) the pull-down abilities of the selection circuit 1010, the selection circuit 1020, and the selection circuit 1030 when the assist circuit 1221 is turned on, and the logic levels of the selection signals OPT1-OPT3 are determined according to practical requirements. Thus, this can selectively turn on one or more of the selection switch M1, the selection switch M2, and the selection switch M3 so as to determine (e.g., delay) the timing point (e.g., the timing point TP2) when the dummy bit line signal DBL is pulled down to the predetermined voltage.

In addition, in some other embodiments, the selection circuit 1010, the selection circuit 1020, and the selection circuit 1030 may not be implemented by the selection circuit 310, the selection circuit 320, and the selection circuit 330 in FIG. 3. In these embodiments, taking the selection circuit 1010 as an example, the selection circuit 1010 can include multiple transistors, some of the transistors are controlled by the under-drive signal UD, and other transistors are controlled by the dummy word line signal DWL.

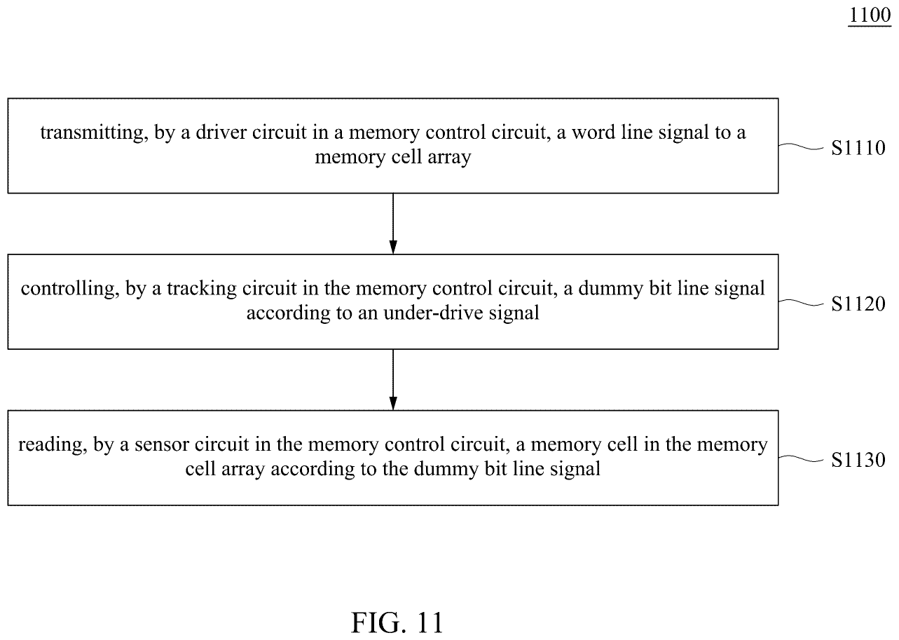

Reference is made to FIG. 11. FIG. 11 is a schematic diagram of a reading method 1100 according to some embodiments of the present disclosure.

As illustrated in FIG. 11, the reading method 1100 includes operation S1110, operation S1120, and operation S1130. In some embodiments, the reading method 1100 is applied to the memory device 100 in FIG. 1, but the present disclosure is not limited thereto. For better understanding, the reading method 1100 is described in the following paragraph with reference to the memory device 100 in FIG. 1 and the waveforms in FIG. 2.

In operation S1110, the driver circuit 122 in the memory control circuit 120 transmits the word line signal WL to the memory cell array 110, in which the driver circuit 122 includes the assist circuit 1221. In operation S1120, the tracking circuit 126 in the memory control circuit 120 controls the dummy bit line signal DBL according to the under-drive signal UD. When the assist circuit 1221 is turned off, the under-drive signal UD has the higher voltage V2. When the assist circuit 1221 is turned on, the under-drive signal UD has the lower voltage V5. In operation S1130, the sensor circuit 128 in the memory control circuit 120 reads the memory cells 111 in the memory cell array 110 according to the dummy bit line signal DBL.

The details about these operations mentioned above are described in previous embodiments, so they are not described herein again.

As described above, in the present disclosure, by the assist circuit, the under-drive signal can be used to adjust (e.g., weaken) the pull-down ability of the tracking circuit to control (e.g., delay) the timing point when the dummy bit line signal is pulled down to the predetermined voltage. This extended time allows the voltage difference between the bit line signal and the complementary bit line signal to be large enough to be read out correctly.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising:
a memory cell array coupled to a plurality of bit lines and a plurality of complementary bit lines; and
a memory control circuit coupled to the memory cell array, wherein the memory control circuit comprises:
a driver circuit configured to transmit a word line signal to the memory cell array, wherein the driver circuit comprises an assist circuit;
a tracking circuit configured to control a dummy bit line signal according to an under-drive signal; and
a sensor circuit coupled to the plurality of bit lines and the plurality of complementary bit lines, and configured to read a memory cell in the memory cell array according to the dummy bit line signal,
wherein when the assist circuit is turned off, the under-drive signal has a first voltage,
wherein when the assist circuit is turned on, the under-drive signal has a second voltage,
wherein the second voltage is lower than the first voltage.

2. The memory device of claim 1, wherein when the assist circuit is turned off, the word line signal has a third voltage, wherein when the assist circuit is turned on, the word line signal has a fourth voltage, wherein the fourth voltage is lower than the third voltage.

3. The memory device of claim 1, wherein when the assist circuit is turned off, the under-drive signal has a first pulse width, wherein when the assist circuit is turned on, the under-drive signal has a second pulse width, wherein the second pulse width is wider than the first pulse width.

4. The memory device of claim 1, wherein when the assist circuit is turned off, the word line signal has a first pulse width, wherein when the assist circuit is turned on, the word line signal has a second pulse width, wherein the second pulse width is wider than the first pulse width.

5. The memory device of claim 1, wherein the sensor circuit comprises:
an inverter configured to invert the dummy bit line signal to generate an enable signal; and
a plurality of sensing amplifiers coupled to the plurality of bit lines and the plurality of complementary bit lines, and configured to be enabled according to the enable signal.

6. The memory device of claim 1, wherein the tracking circuit is configured to pull down the dummy bit line signal according to the under-drive signal, a dummy word line signal, and a plurality of selection signals.

7. The memory device of claim 6, wherein when the assist circuit is turned off, the dummy word line signal has a first pulse width, wherein when the assist circuit is turned on, the dummy word line signal has a second pulse width, wherein the second pulse width is wider than the first pulse width.

8. The memory device of claim 6, wherein the tracking circuit comprises:
a plurality of selection circuits coupled between a dummy bit line and a ground terminal, and controlled by the under-drive signal to pull down the dummy bit line signal on the dummy bit line.

9. The memory device of claim 8, wherein the plurality of selection circuits have different pull-down abilities for pulling down the dummy bit line signal.

10. The memory device of claim 8, wherein the tracking circuit further comprises:
a pull-down switch coupled between the dummy bit line and the plurality of selection circuits, and controlled by the dummy word line signal.

11. The memory device of claim 10, wherein the plurality of selection circuits are further controlled by the plurality of selection signals respectively.

12. The memory device of claim 10, wherein the tracking circuit further comprises:
a plurality of selection switches coupled between the plurality of selection circuits and the ground terminal respectively, and controlled by the plurality of selection signals respectively.

13. The memory device of claim 10, wherein the tracking circuit further comprises:
a plurality of selection switches coupled between the pull-down switch and the plurality of selection circuits respectively, and controlled by the plurality of selection signals respectively.

14. The memory device of claim 8, wherein the plurality of selection circuits are further controlled by the dummy word line signal and are further controlled by the plurality of selection signals respectively.

15. The memory device of claim 8, wherein the tracking circuit further comprises:
a plurality of selection switches coupled between the selection circuits and the ground terminal respectively, and controlled by a plurality of combination signals of the plurality of selection signals and the dummy word line signal respectively.

16. The memory device of claim 8, wherein the tracking circuit further comprises:
a plurality of selection switches coupled between the dummy bit line and the plurality of selection circuits respectively, and controlled by a plurality of combination signals of the plurality of selection signals and the dummy word line signal respectively.

17. The memory device of claim 8, wherein the tracking circuit further comprises:
a plurality of selection switches coupled between the plurality of selection circuits and the ground terminal respectively, and controlled by the plurality of selection signals respectively, wherein the plurality of selection circuits are controlled by the under-drive signal and the dummy word line signal.

18. The memory device of claim 8, wherein the tracking circuit further comprises:
a plurality of selection switches coupled between the dummy bit line and the plurality of selection circuits respectively, and controlled by the plurality of selection signals respectively, wherein the plurality of selection circuits are controlled by the under-drive signal and the dummy word line signal.

19. A memory control circuit, comprising:
a driver circuit configured to transmit a word line signal to a memory cell array, wherein the driver circuit comprises an assist circuit;
a tracking circuit configured to control a dummy bit line signal according to an under-drive signal; and
a sensor circuit coupled to a plurality of bit lines and a plurality of complementary bit lines, and configured to read a memory cell in the memory cell array according to the dummy bit line signal,
wherein when the assist circuit is turned off, the under-drive signal has a first voltage,
wherein when the assist circuit is turned on, the under-drive signal has a second voltage,
wherein the second voltage is lower than the first voltage.

20. A reading method of a memory device, wherein the reading method comprises:
transmitting, by a driver circuit in a memory control circuit, a word line signal to a memory cell array, wherein the driver circuit comprises an assist circuit;
controlling, by a tracking circuit in the memory control circuit, a dummy bit line signal according to an under-drive signal, wherein when the assist circuit is turned off, the under-drive signal has a first voltage, wherein when the assist circuit is turned on, the under-drive signal has a second voltage, wherein the second voltage is lower than the first voltage; and
reading, by a sensor circuit in the memory control circuit, a memory cell in the memory cell array according to the dummy bit line signal.
